(19) United States
(12) Patent Application Publication
(10) Pub. No.: US 2022/0322676 A1
(43) Pub. Date: Oct. 13, 2022

(54) SYSTEMS AND METHODS FOR PHYSICAL VAPOR DEPOSITION OF SILICON NITRIDE COATINGS HAVING ANTIMICROBIAL AND OSTEOGENIC ENHANCEMENTS

(71) Applicant: SINTX Technologies, Inc., Salt Lake City, UT (US)

(72) Inventors: Bryan J. McEntire, Salt Lake City, UT (US); Ryan M. Bock, Salt Lake City, UT (US); Bhajanjit Singh Bal, Salt Lake City, UT (US)

(21) Appl. No.: 17/715,642

(22) Filed: Apr. 7, 2022

Related U.S. Application Data
(60) Provisional application No. 63/171,957, filed on Apr. 7, 2021.

(51) Int. Cl. A01N 59/00; H01J 37/34; C23C 14/35; C23C 14/06

(52) U.S. Cl. CPC A01N 59/00; H01J 37/3405; C23C 14/35; C23C 14/0652; H01J 2237/332

(57) ABSTRACT

Disclosed herein are systems and methods for physical vapor deposition silicon nitride coatings. The methods thereof may include a creating a magnetically confined plasma near a surface of a silicon nitride. The plasma may cause positively charged energetic ions from the plasma to collide with negatively charged silicon nitride atoms, causing the silicon nitride atoms to be sputtered and deposited on a substrate such as titanium. The silicon nitride coating may be nitrogen-rich silicon nitride or silicon-rich silicon nitride.

### CROSS-REFERENCE TO RELATED APPLICATIONS

This application claims priority to U.S. Provisional Application No. 63/171,957, filed Apr. 7, 2021, the contents of which are entirely incorporated by reference herein.

### FIELD

The present disclosure relates to the physical vapor deposition of silicon nitride coatings, and in particular, to systems and methods for magnetron sputtering physical vapor deposition coatings that provide antimicrobial and osteogenic enhancements to substrates.

### BACKGROUND

The osteogenic, osteoconductive, and antipathogenic properties of bulk silicon nitride (Si₃N₄) ceramics have been tested in various biological conditions and against different strains of bacteria and viruses. However, the biological effects of various stoichiometric and non-stoichiometric Si/N ratios or atomic percentages (at. %) for silicon nitride ceramics are unknown. One method of determining the effect of different Si/N ratios or percentages is to utilize physical vapor deposition (PVD) to deposit coatings of differing silicon and nitrogen concentrations. PVD coatings are high purity. They can be applied as thin films on metals, plastics, or other ceramics at or near room temperature. In contrast, bulk Si₃N₄ ceramics must be prepared at very high temperatures that exceed the processing and use temperatures of most metals, plastics and many other ceramics. PVD coatings also do not contain the glass phase which is typically necessary for densifying bulk Si₃N₄ ceramics. Thus, PVD Si₃N₄ coatings have the potential to impart enhanced biological properties to other materials. Thus, there is a need for improvement of the antimicrobial and osteogenic properties of other substrate materials using PVD Si₃N₄ coatings.

It is with these observations in mind, among others, that various aspects of the present disclosure were conceived and developed.

### SUMMARY

A need exists for an improved substrate with enhanced antibacterial and osteogenic properties. In one aspect, a magnetron sputtering PVD apparatus and method is disclosed for applying a plasma-based coating onto a substrate for producing antibacterial and osteogenic enhancements to the substrate. In another aspect, a related method for coating a substrate with silicon nitride is disclosed, wherein the method includes using PVD to coat the substrate with nitrogen-rich silicon nitride or silicon-rich silicon nitride.

In some aspects, the silicon nitride coating is applied using reactive high-power impulse magnetron sputtering. A nitrogen-rich silicon nitride coating may have a nitrogen content of about 58 at. % to about 70 at. % nitrogen. A silicon-rich silicon nitride coating may have a nitrogen content of about 42 at. % to about 56 at. %.

The silicon nitride coating may have antibacterial properties. In some aspects, the silicon nitride coating may have greater antibacterial properties than an uncoated substrate. The silicon nitride coating may contribute to a variation in cell metabolism. The silicon nitride coating may improve osteogenic activity at the substrate surface. In some aspects, the silicon nitride coating may have greater osteogenic activity than an uncoated substrate. The silicon nitride coating may favor deposition of hydroxyapatite. In some aspects, the silicon nitride coating may favor homogenous distribution of the hydroxyapatite. The silicon nitride coating may have greater antibacterial properties and greater osteogenic activity than an uncoated substrate.

The silicon nitride coating may have a thickness ranging from 1 μm to 3 μm. The substrate may include glass or titanium. In some aspects, the substrate may be a surface of a biomedical device, component, or implant. In other aspects, the substrate may be a high contact surface of an object selected from the group consisting of handles, knobs, levers, bed rails, chairs, movable lamps, light switches, cellular phone cases, tray tables, or counters.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The description will be more fully understood with reference to the following figures and data graphs, which are presented as various embodiments of the disclosure and should not be construed as a complete recitation of the scope of the disclosure, wherein:

FIG. 1 is a schematic representation of a magnetron sputtering physical vapor deposition (PVD) apparatus for magnetic sputtering of a PVD coating on a substrate.

FIG. 2 is a schematic representation of the experimental procedures: production of the samples, preliminary characterization, scratch testing and biological testing against Escherichia coli (E. coli) bacteria and with KUSA-A1 mammalian cells.

FIG. 3A is an image of an uncoated glass disc; FIG. 3B is an image of a nitrogen-rich Si₃N₄-coated glass disc; FIG. 3C is an image of a silicon-rich Si₃N₄-coated glass disc; and FIG. 3D is an image of a stoichiometric Si₃N₄-coated glass disc.

FIG. 4 is an FTIR spectra of the three coatings compared with the signal of the silica SLS glass substrate.

FIG. 5A is a graph of CFU/mm² as measured after 24 and 48 hours of in vitro exposure of PEEK, monolithic Si₃N₄, glass, and PVD Si₃N₄-coated glass samples to E. coli. The error bars on the chart depict calculated standard error for each sample group.

FIG. 5B is a graph of CFU/mm² as measured after 24 and 48 hours of in vitro exposure of PEEK, monolithic Si₃N₄, glass, and PVD Si₃N₄-coated glass samples to S. epidermidis. The error bars on the chart depict calculated standard error for each sample group.

FIG. 6A shows an arrangement of images for a Luciferase assay performed on an uncoated glass disc; FIG. 6B shows an arrangement of images for a Luciferase assay performed on a nitrogen-rich Si₃N₄-coated glass disc; FIG. 6C shows an arrangement of images for a Luciferase assay performed on a silicon-rich Si₃N₄-coated glass disc, and FIG. 6D shows an arrangement of images for a Luciferase assay performed on a stoichiometric Si₃N₄-coated glass disc.

FIGS. 7A-7H show surface characterization after testing with KUSA-A1 for 48 hours. FIG. 7A is a laser microscopy image of the uncoated glass disc; FIG. 7B is a laser microscopy image of a nitrogen-rich Si₃N₄-coated glass disc; FIG. 7C is a laser microscopy image of a silicon-rich Si₃N₄-coated glass disc; FIG. 7D is a laser microscopy image of a stoichiometric Si₃N₄-coated glass disc; FIG. 7E is a scanning electron microscopy image of an uncoated glass disc; FIG. 7F is a scanning electron microscopy image of a nitrogen-rich Si₃N₄-coated glass disc; FIG. 7G is a scanning electron microscopy image of a silicon-rich Si₃N₄-coated glass disc; and FIG. 7H is a scanning electron microscopy image of a stoichiometric Si₃N₄-coated glass disc.

FIG. 8 shows WST optical density as measured on the samples after 1 week of in vitro testing with KUSA-A1.

FIG. 9 shows hydroxyapatite specific volume as calculated using laser microscopy on the surface of the different samples, after in vitro testing with KUSA-A1 .

FIG. 10 shows the area ratio covered by ALP (%).

FIG. 11 is an FTIR spectra acquired on the surface of the different samples after in vitro testing with KUSA-A1.

FIG. 12 is a graph of the crystallinity index, expressed as the ratio between the intensity of the band at 1030 cm⁻¹ and assigned to highly crystalline hydroxyapatite against the intensity of the band at 1010 cm⁻¹ assigned to poorly crystalline material.

FIG. 13 is a graph of carbonate to phosphate ratio as measured by comparing the intensity of the band at about 1450 cm⁻¹ and associated to v3CO₃²⁻ vibrations and the band at about 1050 cm⁻¹ associated to PO₄³⁻.

FIG. 14 is a graph of the mineral to matrix ratio, expressed as the ratio between the intensity of the band at 1050 cm⁻¹ associated to PO₄³⁻ and the intensity of the band at about 1700 cm⁻¹ relative to amide I.

FIG. 15 is a graph of the amount of S. epidermidis present on N-rich PVD SN on titanium, stoichiometric PVD SN on Ti, Si-rich PVD SN on titanium, AFSN, titanium, and PEEK at 24 hours and at 48 hours.

Corresponding reference characters indicate corresponding elements among the view of the drawings. The headings used in the figures do not limit the scope of the claims.

### DETAILED DESCRIPTION

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Reference to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Thus, references to one or an embodiment in the present disclosure can be references to the same embodiment or any embodiment; and, such references mean at least one of the embodiments.

As used herein, the terms “comprising,” “having,” and “including” are used in their open, non-limiting sense. The terms “a,” “an,” and “the” are understood to encompass the plural as well as the singular. Thus, the term “a mixture thereof” also relates to “mixtures thereof.”

As used herein, the term “silicon nitride” includes Si₃N₄, a-Si₃N₄, β-Si₃N₄, SiYAlON, SiYON, SiAlON, or combinations thereof.

Generally, the ranges provided are meant to include every specific range within, and combination of sub ranges between, the given ranges. Thus, a range from 1-5, includes specifically 1, 2, 3, 4 and 5, as well as sub ranges such as 2-5, 3-5, 2-3, 2-4, 1-4, etc. All ranges and values disclosed herein are inclusive and combinable. For examples, any value or point described herein that falls within a range described herein can serve as a minimum or maximum value to derive a sub-range, etc. Other than in the operating examples, or where otherwise indicated, all numbers expressing quantities of ingredients and/or reaction conditions may be modified in all instances by the term “about,” meaning within +/−5% of the indicated number.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

Provided herein are systems and methods for physical vapor deposition (PVD) of silicon nitride coatings applied to a surface of a substrate to provide antibacterial, antiviral, and osteogenic enhancements. The PVD coating may be used to produce stoichiometric, silicon rich (Si-rich), or nitrogen rich (N-rich) silicon nitride coatings on a surface of a substrate. In some embodiments, silicon rich coatings may enhance osteogenesis and osteoconductivity and nitrogen rich coatings may have an increased antimicrobial effect. In some embodiments, a magnetron sputtering PVD apparatus is disclosed that uses a technique for coating silicon nitride films having excellent adhesive and high density characteristics. In one aspect, a plasma-based coating process may be utilized where magnetically confined plasma is created near the surface of a target material for applying a magnetron sputtered PVD silicon nitride-coating on the substrate. In some examples, the PVD coating may be applied to the substrate using reactive high-power impulse magnetron sputtering (R-HIPIMS).

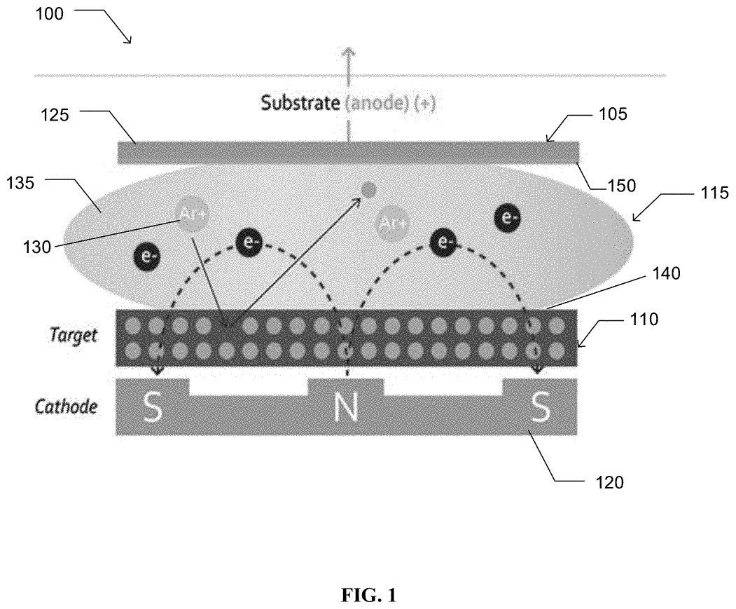

FIG. 1 is a schematic representation of a magnetron sputtering PVD apparatus 100 for coating a substrate with silicon nitride. In some embodiments, the magnetron sputtering PVD apparatus 100 utilizes a plasma-based vacuum deposition method for producing thin films and coatings by creating a magnetically confined plasma 135 near the surface of a silicon nitride target material. The magnetron sputtering PVD apparatus 100 may receive a substrate 105 to be coated with silicon nitride 110 in a vacuum chamber 115 of the magnetron sputtering PVD apparatus 100. In some embodiments, the vacuum chamber 115 may have a cathode 120 and an anode 125 arranged such that the cathode 120 and the anode 125 are spaced apart. In one particular arrangement, the anode 125 may be placed above the cathode 120. In at least one example, the substrate 105 acts as the anode 120.

The disclosed method of coating includes receiving silicon target 110 in the vacuum chamber 115 with the silicon target 110 being inserted between the cathode 120 and the anode 125.

In one aspect, the disclosed method of coating may include reducing the pressure within the vacuum chamber 110 from an initial pressure to a base pressure. The base pressure may be a pressure between 3 μbar and 9 μbar. In at least one embodiment, the base pressure is 5 μbar.

The disclosed method of coating may further include receiving a gas 130 within the vacuum chamber 115. The gas may comprise nitrogen or argon.

As noted above, the disclosed method of coating may also include generating a plasma inside the chamber with a power rating of between 300 and 900 W and applying a bias voltage between the cathode 120 and the anode 125. In some embodiments, the bias voltage ranges between 70 V and 180 V. Applying the voltage between the cathode 120 and the anode 125 causes the gas 130 to ionize into a plasma 135. In one aspect, the plasma 135 may be magnetically confined near a surface 140 of the silicon nitride 110.

Applying a voltage between the cathode 120 and the anode 125 of the magnetron sputtering PVD apparatus 100 can cause collisions between plasma cations and the silicon target 110. Such collisions can cause silicon 110 atoms to be ejected into the plasma where they reactive with nitrogen gas and subsequently are deposited on a substrate surface 150 of the substrate 105. In other words, the plasma causes positively charged energetic ions from the plasma to collide with negatively charged silicon target atoms such that the silicon nitride atoms are sputtered from the surface, reacted with nitrogen, and deposited on a substrate.

In some embodiments, the PVD silicon nitride coating may include stoichiometric silicon nitride, nitrogen-rich silicon nitride, or silicon-rich silicon nitride. The stoichiometric composition of silicon nitride, Si₃N₄, is 43 at. % silicon and 57 at. % nitrogen. However, when applied as a PVD coating, the ratio of silicon to nitrogen can be varied. In particular, the nitrogen content may be present in the PVD coating in a range from about 42 at. % to about 70 at. %. In a nitrogen rich silicon nitride coating, the coating may have between about 58 at. % to about 70 at. % nitrogen. In a silicon rich silicon nitride coating, the coating may have between about 42 at. % to about 56 at. % nitrogen. In some embodiments, the at. % of nitrogen in the resulting film/coating is controlled by modulating the nitrogen plasma back pressure during deposition, wherein higher nitrogen plasma back pressure correlates to higher concentrations of nitrogen in the resulting film/coating.

In some embodiments, the PVD silicon nitride coating may have a thickness ranging from about 1 μm to about 3 μm. In some examples, a Si-rich coating may have a thickness of about 2.7 μm to about 2.9 μm, a N-rich coating may have a thickness of about 1.7 μm to about 1.9 μm, and a stoichiometric coating may have a thickness of about 1.9 μm to about 2.2 μm. The thickness is limited by the stresses developed during the deposition process. In most cases, thickness cannot exceed about 5 μm. In some embodiments, the PVD silicon nitride coating may have a surface roughness Sa values of about 14 nm to about 33 nm. The roughness may correlate with the thickness of the coatings. In some embodiments, the nitrogen-rich coating may have the highest adhesion strength, followed by the stoichiometric coating, and the silicon-rich coating. For example, the silicon-rich coating may reach a critical scratch load (Lc₃) at a value of about 31 N, while the nitrogen-rich coating may resist up to about 38 N of load.

In some embodiments, the substrate 105 may include glass, titanium, stainless steel, silicon, cobalt-chromium alloys, alumina, zirconia, and other metals or ceramics. Non-limiting examples of the substrate 105 include Ti6Al4V or soda lime silicate (SLS) glass. In at least one example, the substrate 105 may be titanium (Ti6Al4V) discs. In some examples, the substrate 105 may be a surface of a biomedical device, component, or implant. In some instances, the substrate may be configured to be surfaces of implants having improved bioactivity, which is desirable for dental implants, spinal implants, joint components, and the like. Although the substrates may be configured to be medical implants, in some embodiments the substrates may be a high contact surface of an object, such as handles, knobs, levers, bed rails, chairs, movable lamps, light switches, cellular phone cases, tray tables, small counter surfaces, or the like.

Three different PVD coatings based on silicon nitride, but with different Si and N concentrations, may have different osteogenic and antibacterial properties. Due to the low surface roughness, all PVD coatings may prevent the adhesion of bacteria to their surfaces. However, in some examples, the antibacterial effect may be stronger in nitrogen-rich coatings. All PVD silicon nitride coatings may be able to form bone tissue on their surfaces. In some examples, nitrogen-rich coatings may stimulate higher cellular proliferation while silicon-rich materials may stimulate the production of bone tissue with higher mineralization.

In one aspect, the PVD silicon nitride coating may have improved antibacterial properties compared to an uncoated substrate. For example, the PVD coating may contribute to a variation in cell metabolism. Without being limited to any one theory, an increase of nitrogen on the surface of the substrate 105 (e.g. a nitrogen-rich silicon nitride coating) may contribute to a variation in cell metabolism. In at least one example, a substrate PVD coating with nitrogen-rich silicon nitride may have a higher antibacterial behavior as compared to an uncoated substrate 105.

The PVD silicon nitride coating may further improve osteogenic activity at the substrate surface 150. The PVD silicon nitride coating may have greater osteogenic activity than an uncoated substrate. In some examples, PVD silicon nitride coated may provide increased cellular adhesion and osteogenic activity as compared to uncoated substrates. In at least one example, mineralized matrix formation may be higher and more distributed in a silicon-rich silicon nitride coated substrate as compared with an uncoated substrate.

The PVD silicon nitride coating may also promote deposition of hydroxyapatite on the substrate 105. For example, a silicon nitride coated substrate 105 may have an increased deposition of hydroxyapatite on the substrate 105 when implanted in a patient's body as compared to an uncoated substrate. The deposition of hydroxyapatite may be a homogenous distribution. In an example, a silicon-rich coating may promote a homogenous distribution of hydroxyapatite deposition on the substrate's surface. Without being limited to any one theory, the surface chemistry of a silicon-rich coating may favor the deposition of hydroxyapatite distributed homogenously over the surface. In some examples, a silicon-rich silicon nitride PVD coating may provide a high ALP quantification and mineral to matrix ratio as compared to an uncoated substrate.

### EXAMPLES

### Example 1: Glass Substrate

### Sample Production

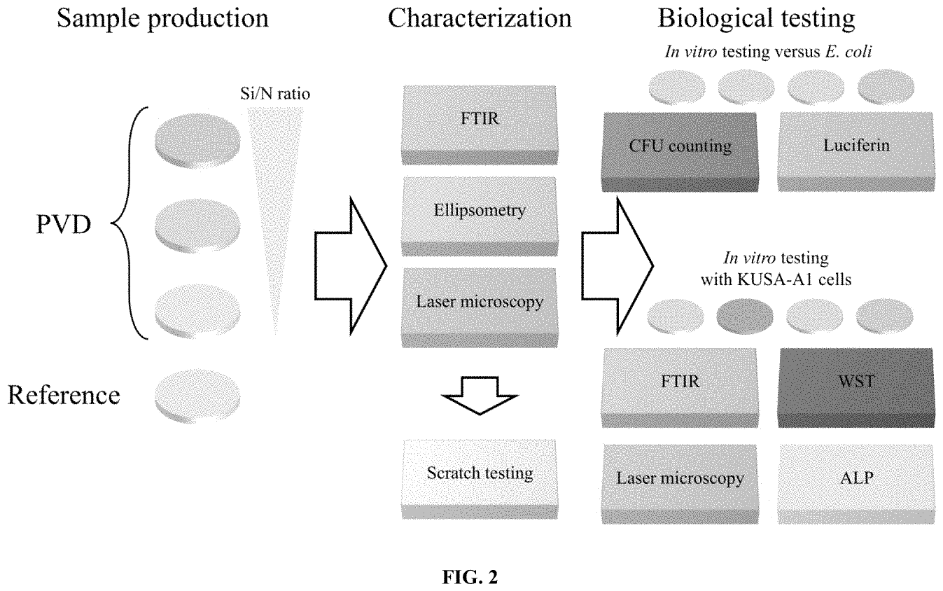

FIG. 2 is an overview of the experimentation performed within the examples.

Standard soda lime silicate (SLS) glass microscope slides were water jet cut into discs (˜ø12.7×1 mm) and subsequently thoroughly cleaned using ultrasonication (10 min at 40 kHz in deionized water at 25° C.) followed by ethanol rinse. They were then coated with Si₃N₄ using physical vapor deposition (PVD) by reactive high-power impulse magnetron sputtering (R-HIPIMS). Process conditions were as follows: frequency 150 kHz; pulse-width 1.5 μs; power 440 W; pressure about 4 Pa; temperature 320° C. The ratio of silicon to nitrogen was controlled by checking the hysteresis curve and nitrogen flow rate while the deposition rate was calculated using silicon witness coupons.

Additional samples used for control and reference purposes in the Staphylococcus epidermidis (S. epidermidis) biofilm assay were discs (˜ø12.7×1 mm) fabricated from monolithic polyether ether ketone (PEEK) and monolithic polycrystalline β-Si₃N₄, whose processing and composition have previously been described elsewhere.

### Sample Characterization

Previously, both chemical and morphological features were suggested to be responsible for the antibacterial and osteoinductive behavior of silicon nitride. However, in these Examples, the morphological effects may be almost completely neglected because of the use of flat mirror polished SLS glass as a substrate for PVD deposition. On the other hand, using PVD results in the formation of an epitaxial layer of material which is not directly equivalent to an anisotropic ceramic bulk. Moreover, the tested PVD coatings do not contain any secondary phases while most of the previous research on biomedical uses of Si₃N₄ was focused on materials containing relatively high amounts of a secondary SiAlYON intergranular amorphous phase.

Film thickness measurements were performed using a Dektak 3030ST Optical Surface Profilometer. The instrument was calibrated before testing and the calibration was verified using thickness standard.

Scratch adhesion measurements were performed according to ASTM C1624-05 using a Rockwell diamond indenter with 200 μm tip. The measurements were performed using a progressive loading up to 40N at a loading rate of 50 N/min and a scratch length of 5 mm on the glass samples.

The surface morphology of the samples before and after biological testing, was analyzed using a confocal scanning laser microscope. All images were collected at various magnifications ranging from 10× to 150×. Initial roughness values were measured on 10 randomized 100×100 μm square areas per sample.

Fourier Transformed Infra-Red Spectroscopy (FT-IR) spectra were collected at room temperature using a FT-IR Spectrometer equipped with a Michelson 28 degree interferometer with corner-cube mirrors, covering a range between 250,000 and 5 cm⁻¹. The aperture size was 200×200 μm² and the acquisition time was set to 30 seconds. The instrument was operated using a dedicated software. Ten different spectra were acquired for each sample before and after biological testing.

A field-emission-gun scanning electron microscope was used to observe the coated samples. The instrument was equipped with an Electron Dispersive X-ray Diffraction (EDS) probe. All images were collected at an acceleration voltage of 10 kV and magnifications between 100× and 50000×. All samples were sputter-coated with a thin (20 to 30 Å) platinum layer.

The culture medium was prepared in accordance with a previous protocol. Specifically, phosphate buffered saline (PBS) was used to mimic blood ion concentrations and was supplemented with 7% glucose, added as an energy source, and 10% human plasma, included as a source of proteins. Separate media samples were inoculated with Escherichia coli (E. coli) and S. epidermidis and agitated on a shaking incubator at 37° C. and 175 rpm for 24 hours until a concentration of 10⁵ cells/mL of growth had been achieved. Then, each disc was inoculated with the bacterial solution within individual well plates. The well plates were subsequently placed on the shaking incubator for 24 hours or 48 hours at 37° C. and 120 rpm. All 48 hour coupons underwent a media refresh at 24 hours (7 mL) to eliminate the possibility of nutrient insufficiency affecting the results.

KUSA A1 cells were cultured for 10 days on the sample surfaces with three changes of medium. The normal medium was composed of DMEM (D-glucose, L-glutamine, phenol red, and sodium pyruvate), 10% FBS (Fetal Bovine Serum) with SNP (sodium nitroprusside) (2%). The culture with the osteoinductive factor was performed with 50 mg/mL of ascorbic acid, 10 mM b-glycerol phosphate, 100 mM hydrocortisone, 10% FBS added to 4.5 g/L of glucose DMEM. After culture, the cells were fixed on the samples with 4% formaldehyde for FTIR and Laser microscope analysis.

### Biological Characterization

Samples were analyzed at 2 time points, either 24 hours or 48 hours, after rinsing with 5 mL of PBS. The procedure was followed by cleaning in a fresh well plate on a shaking incubator for 2 mins at 120 rpm. Samples were subsequently gently dip-rinsed in PBS to remove planktonic bacteria and placed in a 50 mL centrifuge tube along with 10 mL of fresh PBS, which was followed by vigorous vortexing for 2 mins. The bacterial solution was serially diluted as necessary (i.e., 1/10×, 1/100×, 1/1,000×, and 1/10,000×) and plated onto Petrifilm™. The samples were then incubated at 37° C. for 24 hours and 48 hours in stacks of less than 20 films. At the time of testing, the number of colonies on each Petrifilm™ was counted and recorded. The results were multiplied by applicable dilution factors and divided by surface area to determine the average colony forming units' density (CFU/mm²).

Samples used for E. coli in vitro experiments were subjected to luciferase firefly gene transformation testing. A solution containing luciferin was added on the top of the samples. Upon reaction among adenosine triphosphate, Mg²⁺, O₂, and luciferase enzyme, a “glowing” chemiluminescent signal was captured by means of a CCD camera.

At 48 hours of E. coli testing, alkaline phosphatase (ALP) staining was performed. The ALP activity was determined by an assay kit.

The metabolic activity of the bacteria was observed using a colorimetric assay (Microbial Viability Assay Kit-WST). This assay employed an indicator (WST-8), which produced a water-soluble formazan dye upon reduction in the presence of an electron mediator. The amount of the formazan dye generated was directly proportional to the number of living micro-organisms. Solutions were analyzed using microplate readers by collecting optical density values related to living cell concentrations.

### Statistical Analysis

All biological tests were performed on 5 different specimens for each substrate. Spectroscopic analyses were performed on 25 randomized locations for each sample. Scratch tests and thickness measurements were repeated 3 times.

### Surface Characterization

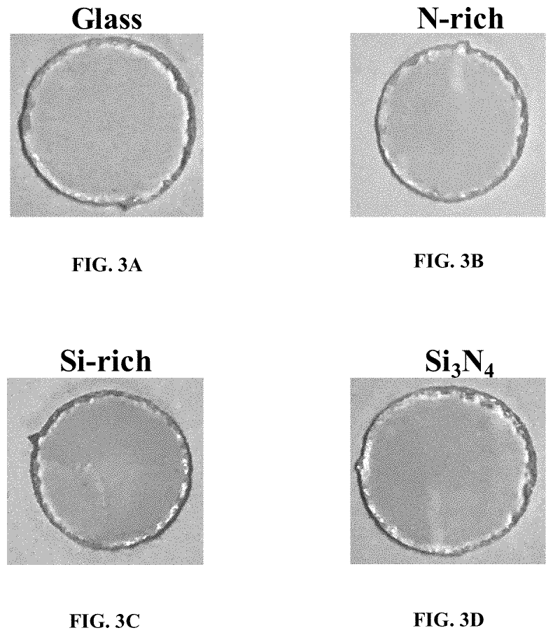

FIG. 3A shows an uncoated glass disc, FIG. 3B shows a nitrogen-rich Si₃N₄-coated glass disc, FIG. 3C shows a silicon-rich Si₃N₄-coated glass disc, and FIG. 3D is a stoichiometric Si₃N₄-coated glass disc.

Coating thickness, surface roughness, and scratch adhesion for the different samples, as measured respectively by optical profilometer, laser microscope and Rockwell indenter, are presented in Table 1 below.

| | Thickness | Roughness Sa | Scratch adhesion | |
|---|---|---|---|---|
| Sample | [μm] | [nm] | Lc₁ [N] | Lc₃ [N] |
| Si-rich | 2.83 ± 0.10 | 24 ± 9 | 15.5 ± 2.5 | 31 ± 0.5 |
| Si₃N₄ | 2.06 ± 0.17 | 21 ± 5 | 18.5 ± 1.5 | 37 ± 1.0 |
| N-rich | 1.82 ± 0.06 | 18 ± 4 | 15.5 ± 3.5 | 38 ± 1.0 |
| Glass | — | 17 ± 3 | — | — |
| substrate | | | | |

It was observed that all coatings were about 2 μm thick, the silicon rich being the thickest at about 2.8 μm and the nitrogen-rich the thinnest at approximately 1.8 μm. Differences in thickness were attributed to the higher deposition rate of silicon as compared to reactive nitrogen. However, the resulting surface morphologies were quite similar, without any detectable droplet or pinholes at all investigated magnifications. As a consequence, the surface roughness of all three samples were comparable to the values of the uncoated glass substrate and in the range of a few nanometers (Sa). Again, the roughness correlated with the thickness of the layers. PEEK and β-Si₃N₄ samples, included as references in the S. epidermidis biofilm assay, exhibited Sa values of 266±49 nm and 665±181 nm, respectively, as measured by laser microscopy.

Scratch testing showed the highest adhesion strength for the nitrogen-rich coating, followed by the stoichiometric condition and the silicon-rich sample. Differences in delamination resistance were associated with several parameters including hardness, elastic modulus, chemical bonding, crystallinity, and orientation. Between the three samples, the silicon-rich coating was the softer, and the critical scratch load (Lc₃) was reached at a lower value (31 N) because it plastically deformed under the diamond tip, exposing the substrate. On the other hand, the nitrogen-rich coating produced the hardest surface, producing cracks under the load of the indenter but resisting up to 38 N of load.

### FTIR

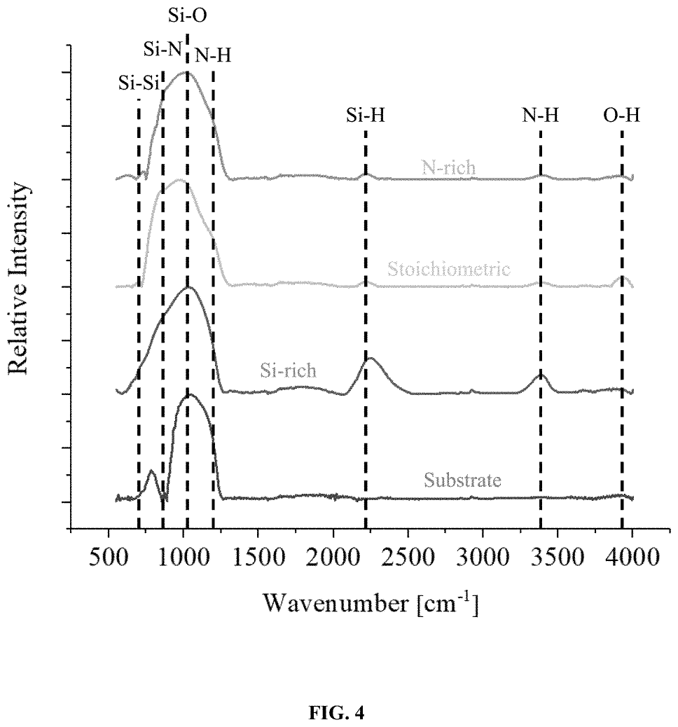

The results of the FTIR spectroscopic analysis are presented in FIG. 4. All four spectra were dominated by the strong Si—O vibration, which is located at about 1050 cm⁻¹. All coated samples showed a secondary, relatively intense peak at a lower wavenumber (700 cm⁻¹), associated with Si—N vibrations due to the Si₃N₄ coating. This band is relatively more intense (about 1.2×) for the nitrogen-enriched coating with respect to the stoichiometric condition, while the silicon-enriched sample has a sensibly lower band intensity (about 0.7 times). At lower wavenumbers, close to 500 cm⁻¹, the band related to Si—Si vibrations was only observed for the Si-rich coating, partially covered by the more intense Si—N band. The N—H band situated at about 1200 cm⁻¹ was clearly observed as a shoulder for the N-rich and stoichiometric conditions, with a higher relative intensity for the former. The Si—H vibration band at about 2200 cm⁻¹ was clearly observable on all three coatings conditions but it had a relatively stronger intensity for the silicon-rich condition.

### Bacterial Testing

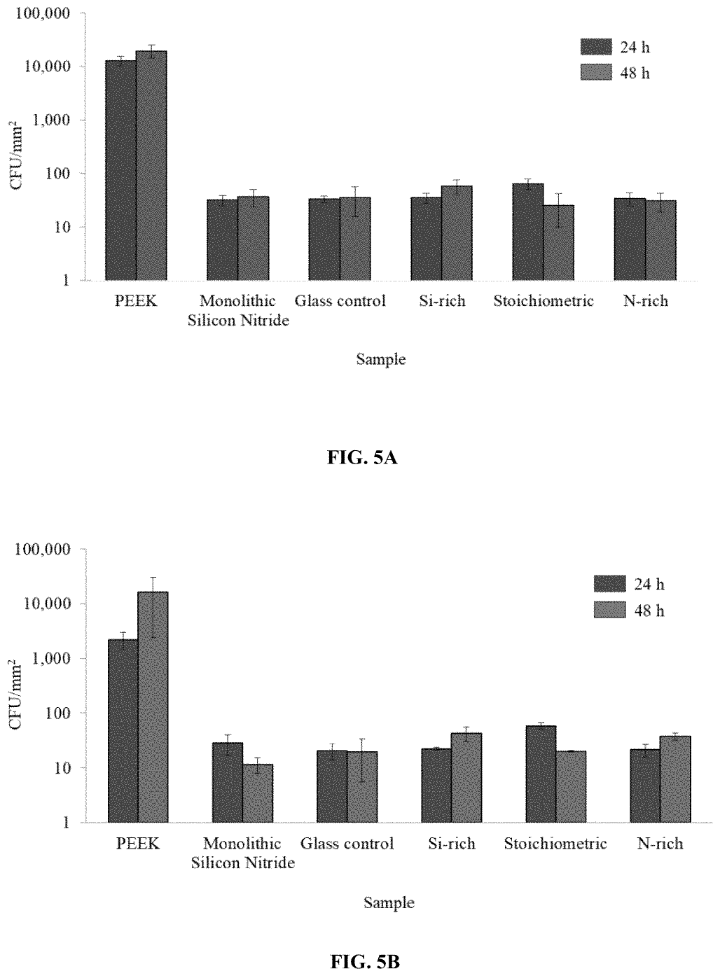

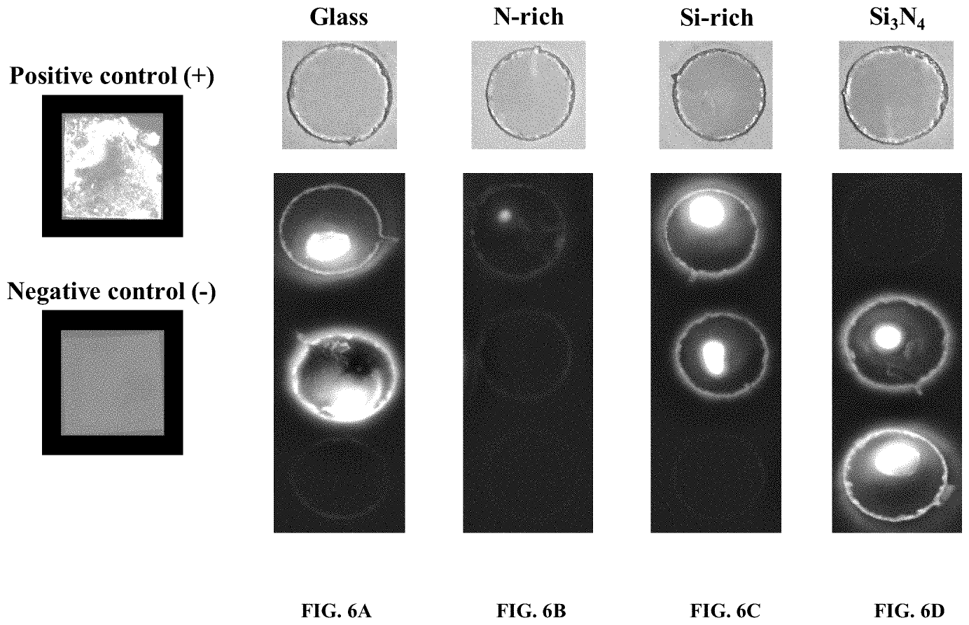

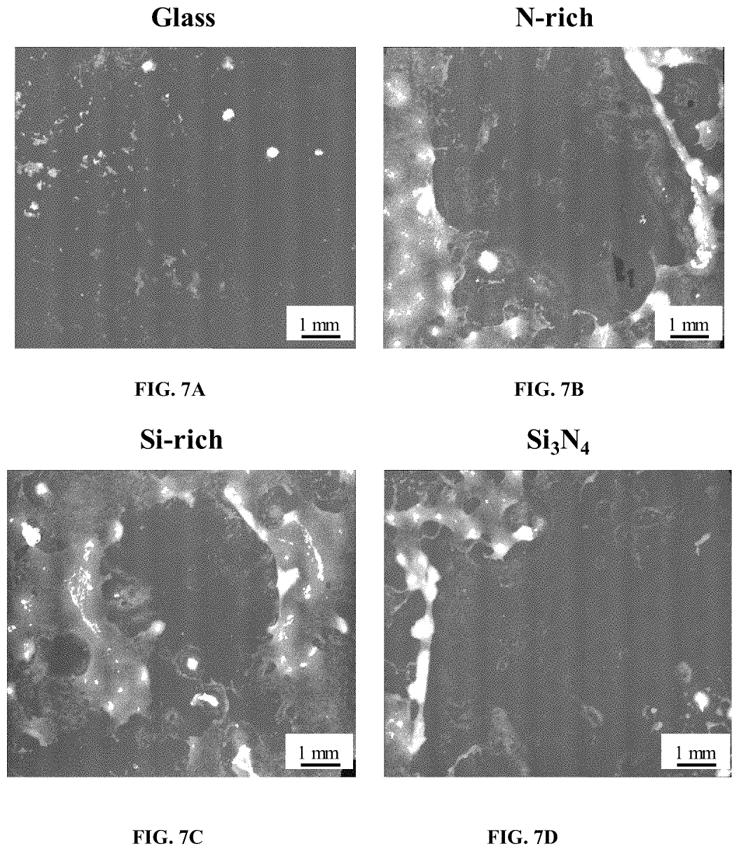

FIG. 5A shows the results for E. coli colony forming units (CFU) after 24 hours and 48 hours of incubation. Values for all samples are relatively low, often comparable to the results of the glass reference samples. This is caused by the almost complete lack of adherence of bacteria to the PVD coatings due to their nanometric surface roughness. At 24 hours, the only statistically higher result was measured on the stoichiometric Si₃N₄. The signal is caused by the formation of a layer of biofilm, as visible on the relative luciferase emission inlet. The peculiar distribution of bacteria observed on the luciferase inlets is caused by higher roughness values that the glass discs have in proximity of the edges, where bacteria could adhere. Nevertheless, no luciferase signal was observed in the case of nitrogen-rich PVD. FIGS. 6A-6D show various images of the PVD coated glass discs being tested using a luciferase assay. As shown, the nitrogen-rich Si₃N₄-coated glass disc of FIG. 6B presented the lowest amount of spots related to bacterial adhesion and proliferation.

The luciferin testing of FIGS. 6A-6D further supports the hypothesis that nitrogen release is the key mechanism that regulates the antibacterial properties of Si₃N₄, as previously speculated. This is in line with previous experiments on silicon-enriched Si₃N₄ bulk materials, which showed lower antibacterial capability when compared to stoichiometric conditions. The presence of a biofilm on the stoichiometric material suggests an initial stage of bacterial adhesion and proliferation. This is also supported by previous literature results showing that the antibacterial effect of silicon nitride is time dependent and reaches an optimal release after about 24 hours. What emerged by the CFU counting was also the increase of bacterial concentration on silicon rich and nitrogen rich PVD coatings, which suggested the occurrence of a series of chemical reactions and the formation of components (NO production, NH3⁺ releasing) that led to the bacterial growth on the surface. However, by luciferase assay, this effect was not detected and the reason behind this is probably due to the low adhesion which occurred on the glass surfaces and Si₃N₄ monolithic bulk comparing with the PEEK.

FIG. 5B shows the results of the biofilm assay performed using S. epidermidis. As expected, the PEEK sample, used as both a positive control and reference biomedical implant material, was heavily colonized and exhibited CFU concentrations 2-3 orders of magnitude higher than the Si₃N₄ groups and glass control. The monolithic polycrystalline β-Si₃N₄ sample, also included as a reference material, harbored minimal bacteria, similar to the low roughness glass control and PVD Si₃N₄ films. At 24 hours, the stoichiometric PVD Si₃N₄ film's CFU concentration was modestly higher (statistically significant) relative to the glass control and other nitride samples, but at 48 h, the bacterial amount decreased significantly. At 48 hours, the monolithic Si₃N₄ sample exhibited the lowest average CFU concentration.

The S. epidermidis biofilm assay (FIG. 5B) demonstrated that the high surface area and soluble glassy secondary phase of the polycrystalline β-Si₃N₄ likely enhanced ammonia release resulting in a greater antibacterial efficacy than would typically be expected for such a high roughness sample.

This effect was also observed in the stoichiometric PVD Si₃N₄ where after an initial S. epidermidis growth at 24 h, an evident decrease of bacteria was detected at 48 h. The big difference of CFU concentration observed between the PEEK and other samples is attributed to the roughness which improved the bacterial adhesion in the case of the positive control. The silicon rich and nitrogen-rich, as in the case of E. coli tests, presented an increase of bacterial concentration over time indicating that the modification on the surface didn't provide any antibacterial improvement.

### Osteoconductivity

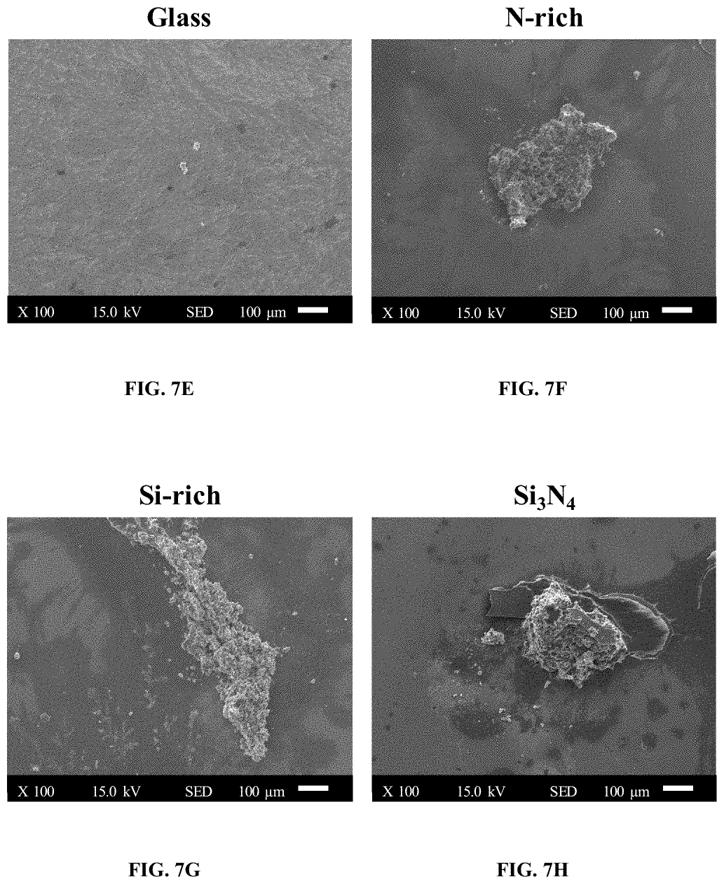

The presence of organic bone tissue formed on the surface of the samples after KUSA-A1 in vitro testing was evaluated using both laser (FIGS. 7A-7D) and electron (FIGS. 7E-7H) microscopy. Unlike the bacteria tests, cells were able to adhere to the smooth surfaces, even if complete coverage was not achieved. The surface of the SLS glass reference (FIGS. 7A and 7E) shows only limited amounts of deposited materials and, in particular, small particles of hydroxyapatite-rich bone tissue, randomly dispersed on the surface. These results are consistent with the data obtained from E. coli testing (FIG. 5A) and indicate a lack of cellular adhesion to the substrates. The coated samples, on the other hand, had an organic phase that could not be removed by washing with demineralized water. For both non-stoichiometric coatings (FIGS. 7B and 7C), the amount of in vitro organic tissue was statistically greater when compared to the stoichiometric condition (FIG. 7D). However, large particles of hydroxyapatite-rich organic tissue were observed on all three samples.

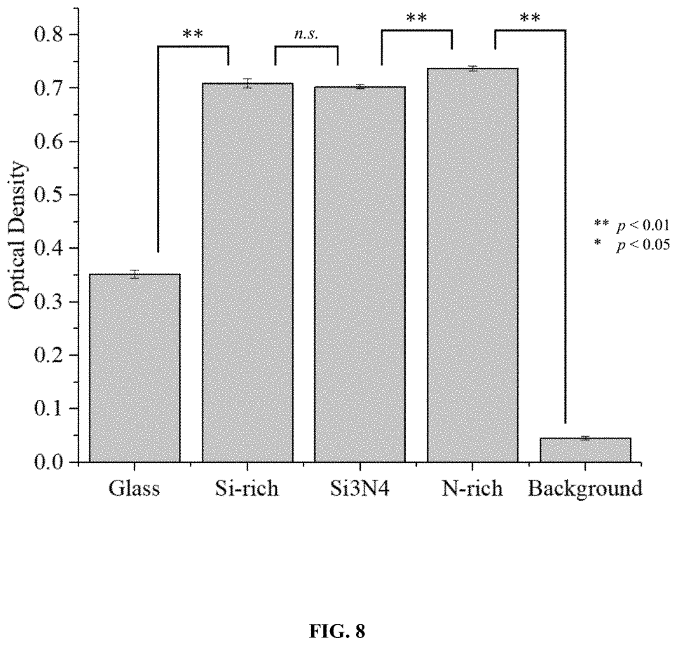

Cell viability test results are presented in FIG. 8. It was observed that all silicon nitride coatings strongly increase cellular viability when compared to the uncoated glass substrate, reaching an optical density of about 0.7. Between the three PVD coatings, the only statistically significant difference was observed for the nitrogen-enriched samples that showed a higher cellular viability, with a value of optical density close to 0.75 along with low statistical dispersion.

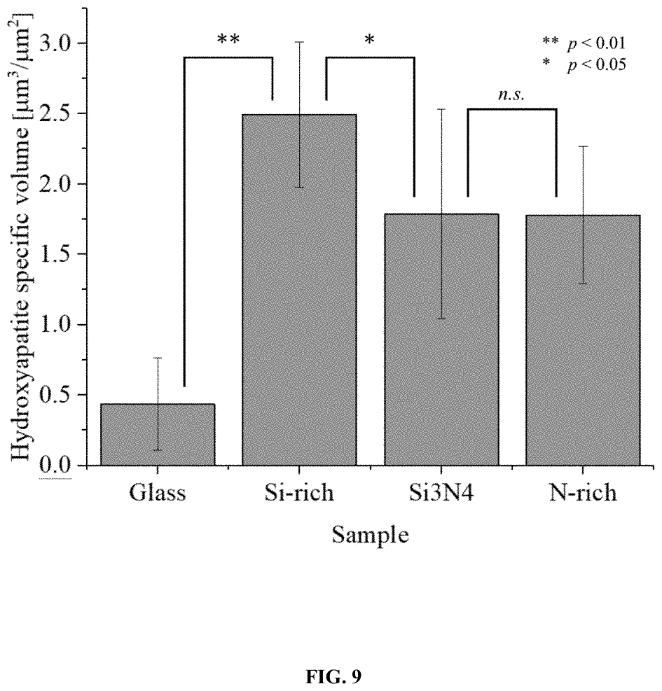

The amount of organic tissue formed on the surface of the samples, as evaluated by laser microscopy is shown in FIG. 9. Even if values are affected by large statistical dispersion due to the non-uniform distribution, the largest amount of specific bone tissue volume (volume of bone per unit of surface) was obtained for the silicon-rich surface. It reached an average amount of tissue 5 times higher than the SLS glass reference. The other two PVD coatings showed statistically lower amounts of specific bone tissue formed, but about 3.5 times respect to the glass.

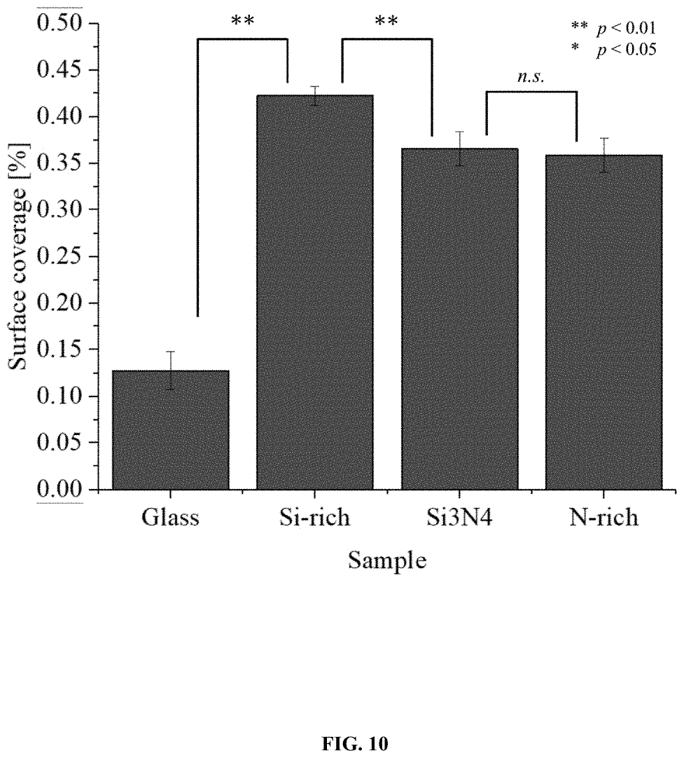

Similar trends were observed for ALP testing, as shown in FIG. 10. Again, the highest values were obtained for the silicon-enriched conditions, while both stoichiometric and nitrogen enriched coatings showed no statistically significant difference. It must be noted that while laser microscopy gives a volumetric evaluation of the amount of tissue formed, ALP reflects the cellular activity on the surface, and it represents a marker for osteoblast differentiation and mineralization. Higher ALP values for the silicon-rich PVD coating reflect enhanced stimulation of the cellular differentiation.

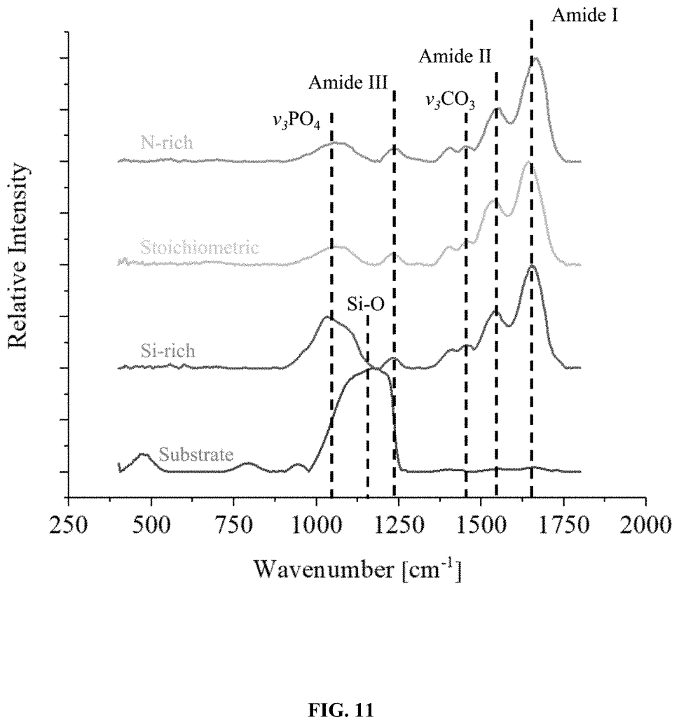

FIG. 11 shows the results obtained by FTIR spectroscopy after testing with KUSA-A1 cells. The spectrum of the reference SLS glass is still dominated by the strong Si—O vibration (previously observed in FIG. 4) at about 1150 cm⁻¹, with almost no signal coming from the region of amide II and I. This result clearly indicates that the amount of bone tissue formed on the reference glass is too small to be properly detected by FTIR. On the other hand, the coated samples produced intense signals from both the mineral fraction of hydroxyapatite (region around 1050 cm⁻¹) and the three amides, confirming formation of greater amounts of bone tissue. Between the coatings, the silicon-enriched coating resulted in the highest fraction of mineral hydroxyapatite.

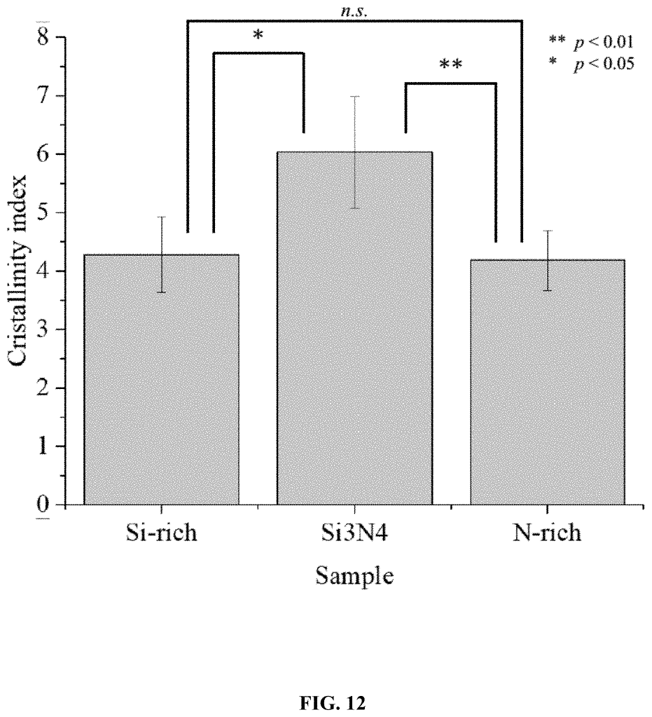

Various quality parameters were extrapolated from FTIR spectroscopy. FIG. 12 shows the hydroxyapatite crystallinity index as previously defined in literature and expressed by the ratio between the intensity of the band at 1030 cm⁻¹ for highly crystalline hydroxyapatite respect to the band at 1010 cm⁻¹ for the poorly crystalline. It was observed that the highest levels of crystallinity were obtained for the stoichiometric condition, while no statistically significant differences were observed for the other two coatings.

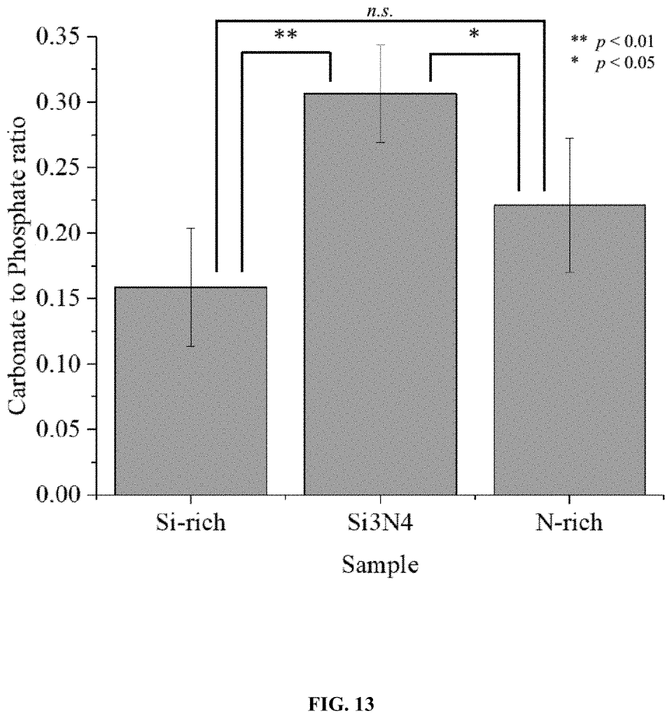

When considering the carbonate to phosphate ratio (FIG. 13), determined from the ratio between the band at about 1450 cm⁻¹ and associated to v3CO₃²⁻ vibrations and the band at about 1050 cm⁻¹ associated to PO₄³⁻, the stoichiometric condition showed higher results when compared to the unbalanced conditions.

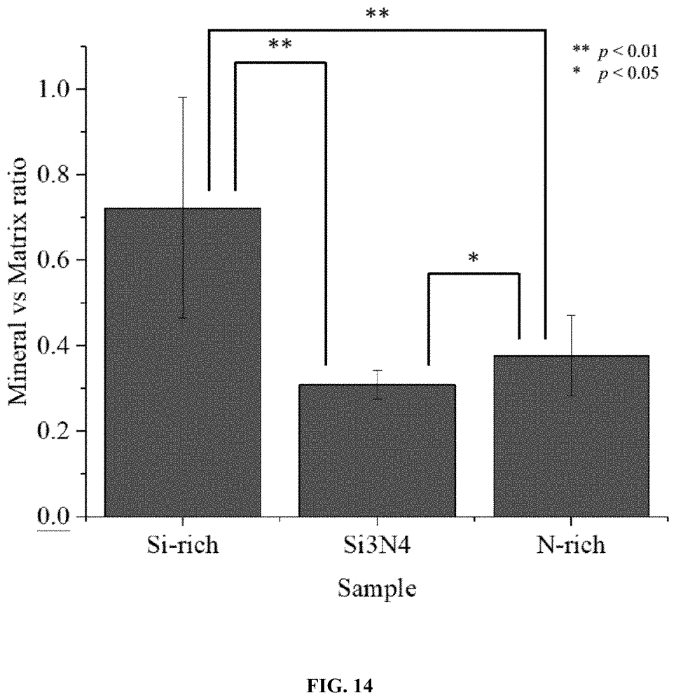

FIG. 14 provides data on the mineral to matrix ratio, expressed as the ratio between the intensity of the band at 1050 cm⁻¹ associated to PO₄³⁻ and the intensity of the band at about 1700 cm⁻¹ relative to amide I. As previously discussed, the FTIR intensity of the phosphate group in FIG. 11 was higher for the silicon-rich sample, which is also reflected in a higher mineral to matrix ratio in FIG. 14.

Testing with KUSA-A1 mesenchymal cells resulted in cellular adhesion and proliferation, as shown in FIGS. 8, 9, and 10. There is a certain degree of chemical interaction between the silicon nitride coatings and the cells, resulting in the formation of a layer of organic matter. This effect is negligible on the SLS glass reference. While the nitrogen enriched coating seems to initially stimulate cellular proliferation (FIG. 8), the silicon-enriched coating resulted in the highest production of bone tissue. Previous results on silicon-enriched laser cladded coatings suggested that silicon regulates the nucleation of hydroxyapatite crystals, thus inducing the formation of higher amounts of bone tissue. On the other hand, the results obtained by ALP (FIG. 10) suggest that in presence of silicon-enriched Si₃N₄, cellular metabolism is also stimulated, after differentiation.

The quality parameters extracted by the FTIR spectra after biological testing with KUSA-A1 show that all three coating strategies stimulate the production of bone tissue, and while the stoichiometric and nitrogen rich conditions seem to produce tissue with highly crystalline hydroxyapatite, silicon results in lower fractions of carbonate substitutions and an overall higher mineralization (FIG. 14). Concerning mechanical properties, it was observed that the adhesion of all coatings was higher than the minimum values requested for biomedical applications by ASTM G171 and ASTM C1624.

### Example 2: Titanium Substrate

In this example, S. epidermidis was used as the biological pathogen on the PVD coated discs (stoichiometric, nitrogen-rich, and silicon-rich), and compared against three control groups—PEEK, uncoated Ti6Al4V, and monolithic silicon nitride. PEEK (ASTM D6262, Ketron® VR PEEK 1000) rod stock was machined into discs. The titanium alloy (ASTM F136, Ti6Al4V-ELI) was machined into discs. Coating of the Ti discs was performed using the identical deposition parameters as described in Example 1. The monolithic silicon nitride discs (AFSN) were produced with a nominal composition of 90 weight % (wt. %) Si₃N₄, 6 wt. % yttrium oxide (yttria, Y₂₃), and 4 wt. % aluminum oxide (alumina, Al₂O₃). All disc samples had the same final form of ø12.7×1˜2 mm. After preparation, treatment, and characterization of the various discs, all samples were sequentially ultrasonically cleaned in ethanol and deionized water for 5 min each. They were then UV-C sterilized (254 nm) for 30 min. A one hour waiting period was observed after sterilization to allow the surfaces to equilibrate.

The medium employed in the bacterial experiments was designed to simulate physiologic fluids, without the presence of cells. Phosphate buffered saline (PBS) was used to mimic blood ion concentrations; 7% glucose was added as an energy source and 10% human plasma was included as a source of proteins. Separate media were inoculated with one colony of S. epidermidis (ATCC® 14990TM) and cultured on a shaking incubator at 37° C. and 175 rpm for 24 h until a concentration of 105 cells/mL of growth had been achieved. Then, each disc was inoculated with the bacterial solution within individual well plates. The well plates were subsequently placed on the shaking incubator for 24 hour or 48 hours at 37° C. and 120 rpm. The 48 hour discs underwent a media refresh at 24 hours (7 mL) to eliminate the possibility of nutrient insufficiency affecting the results. Samples were removed at either 24 hours or 48 hours and rinsed with 5 mL of PBS in a fresh well plate on the shaking incubator for 2 mins at 120 rpm. Samples were subsequently gently dip-rinsed in PBS to remove planktonic bacteria and placed in a 50 mL centrifuge tube along with 10 mL of fresh PBS, which was followed by vigorous vortexing for 2 mins.

The bacterial solution was serially diluted as necessary (e.g., 1/103, 1/1003, 1/1,0003, and 1/10,0003) and plated onto Petrifilm™. The Petrifilm™ was incubated at 37° C. for 24 and 48 hours in stacks of <20 films. At the end of each period, the number of colonies on each Petrifilm™ was counted and recorded. The results were multiplied by applicable dilution factors and divided by surface area to determine the average colony forming units per square millimeter (CFU/mm²).

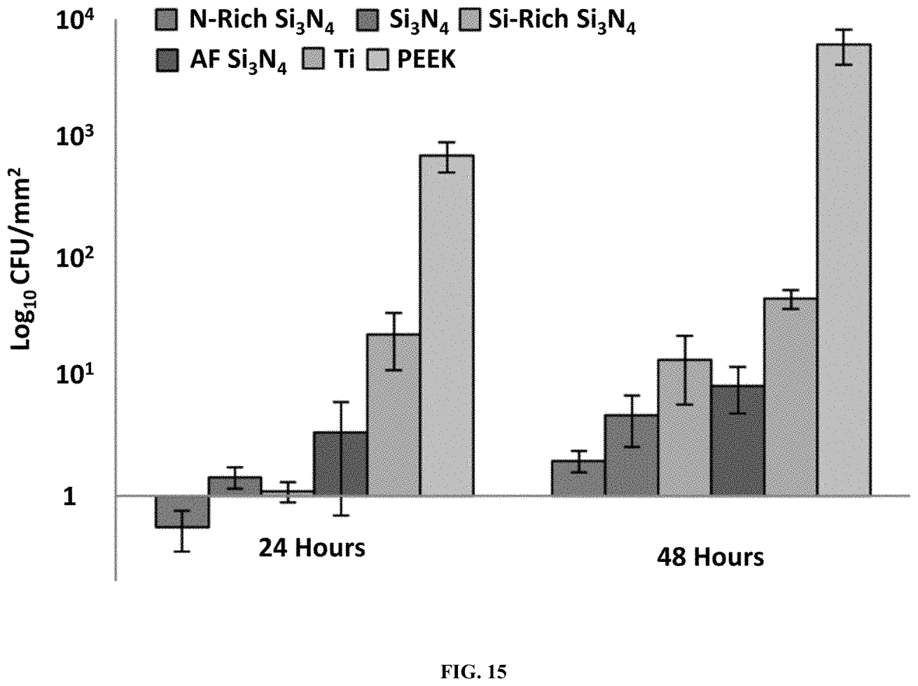

The results, shown in FIG. 15 for the 24-h incubation period show reductions in bacterial load of ˜1.5-log (˜95%), ˜2.5-log (˜99.5%), and >˜2.7-log (˜99.8%) for uncoated Ti6Al4V, AFSN, and the coated Ti6Al4V samples, respectively, in comparison to PEEK. Note that increased nitrogen content in the coating led to even further reductions in bacterial counts with the N-rich coating achieving greater than a 3-log reduction (99.9%). Similar results were obtained for the 48-h incubation period with reductions of approximately 2.5-log (99.5%), 2.7-log (99.8%), 3-log (99.9%), and greater than 2.7-log (99.8%) for the uncoated Ti6Al4V, AFSN, and the coated Ti6Al4V samples, respectively. Note also that the trend of increased nitrogen content in the coating led to further reductions in bacterial counts. The highest nitrogen content coating provided >4-log (99.95%) reduction in bacteria.

Having described several embodiments, it will be recognized by those skilled in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

What is claimed is:

1. A method of coating a substrate with silicon nitride, the method comprising:
providing the substrate;
applying a silicon nitride coating to the substrate using physical vapor deposition,
wherein the silicon nitride coating comprises nitrogen-rich silicon nitride or silicon-rich silicon nitride.

2. The method of claim 1, wherein the silicon nitride coating is applied using reactive high-power impulse magnetron sputtering.

3. The method of claim 1, wherein the silicon nitride coating comprises a nitrogen-rich silicon nitride, wherein the nitrogen content of the coating is about 58 at. % to about 70 at. % nitrogen.

4. The method of claim 1, wherein the silicon nitride coating comprises a silicon-rich silicon nitride, wherein the nitrogen content of the coating is about 42 at. % to about 56 at. %.

5. The method of claim 1, wherein the silicon nitride coating has antibacterial properties.

6. The method of claim 1, wherein the silicon nitride coating contributes to a variation in cell metabolism.

7. The method of claim 1, wherein the silicon nitride coating has greater antibacterial properties than an uncoated substrate.

8. The method of claim 1, wherein the silicon nitride coating improves osteogenic activity at the substrate surface.

9. The method of claim 1, wherein the silicon nitride coating has greater osteogenic activity than an uncoated substrate.

10. The method of claim 1, wherein the silicon nitride coating favors deposition of hydroxyapatite.

11. The method of claim 10, wherein the silicon nitride coating favors homogenous distribution of the hydroxyapatite.

12. The method of claim 1, wherein the silicon nitride coating has greater antibacterial properties and greater osteogenic activity than an uncoated substrate.

13. The method of claim 1, wherein the silicon nitride coating has a thickness ranging from 1 μm to 3 μm.

14. The method of claim 1, wherein the substrate comprises glass or titanium.

15. The method of claim 1, wherein the substrate comprises a surface of a biomedical device, component, or implant.

16. The method of claim 1, wherein the substrate comprises a high contact surface of an object selected from the group consisting of handles, knobs, levers, bed rails, chairs, movable lamps, light switches, cellular phone cases, tray tables, or counters.

17. A silicon nitride coated substrate prepared using the method of claim 1.
